(19) United States
(12) Patent Application Publication
(10) Pub. No.: US 2017/0263414 A1
(43) Pub. Date: Sep. 14, 2017

(54) ELECTRON MICROSCOPE

(71) Applicant: Taiwan Electron Microscope Instrument Corporation, Hsinchu City (TW)

(72) Inventors: FU-RONG CHEN, Hsinchu City (TW); Tsu-Wei HUANG, Taoyuan City (TW); Shih-Yi LIU, Kaohsiung City (TW); I-Jiun CHEN, Hsinchu City (TW); CHIH WEI CHEN, Zhubei City (TW); Ying-Shuo TSENG, Hsinchu City (TW); Yu-Shan HUANG, Hsinchu City (TW); Hsin-Yu LIN, Taitung City (TW); Jian-Min FANG, Kaohsiung City (TW); Chin-Liang HSU, Linluo Township (TW); LI-CHIAO YANG, Hsinchu City (TW)

(21) Appl. No.: 15/174,323

(22) Filed: Jun. 6, 2016

(30) Foreign Application Priority Data
Mar. 14, 2016 (TW) 105107824

(51) Int. Cl. H01J 37/26; H01J 37/16; H01J 37/20

(52) U.S. Cl. CPC H01J 37/26; H01J 37/20; H01J 37/16; H01J 2237/162; H01J 2237/202; H01J 2237/2001

(57) ABSTRACT

An electron microscope includes a charged particle beam generator, a detector, a film and a bearing unit. The charged particle beam generator generates a first charged particle beam to bomb an object. The detector detects a second charged particle from the object to form an image. The film disposes on downstream of charged particle beam generator and has a first surface and a second surface. A space between charged particle beam generator and the first surface of film is a vacuum environment. The bearing unit disposes at a side of second surface of film and has a bearing surface and a back surface. The object disposes on the bearing surface of the bearing unit and a distance between an analyzed surface of the object and the film is less than a predetermined spacing. A liquid space exists between the analyzed surface and the film to be filled a liquid.

### BACKGROUND OF THE INVENTION

1. Field of the Invention

The present invention relates to an electron microscope, and more particularly to an electron microscope for inspecting a liquid or an object immersed in a liquid.

2. Description of the Prior Art

In the present semiconductor processes that need to use a liquid, such as washing, photoresist removal, plating, etching, polishing and so on, the process result can be obtained only after the whole process ends. If a degradation degree of the liquid material itself or a success of the reaction between the liquid material and the reactant can be inspected in real-time during the process, then the process can be controlled more precisely and the yield can be improved.

However, the traditional analyzing equipment for a charged particle beam needs to be in a vacuum environment, and has certain limitation on the observation of a liquid or a water-contained sample, nor can it analyze a base material immersed in a liquid environment. Although an optical inspection is not limited to the requirement of a vacuum environment, a resolution below 100 nm can not be achieved due to the optical wavelength. Even an indirect image analysis, such as dynamic scattering light, is used, a resolution below 20 nm can not be achieved, and therefore, it can not meet the requirement of the semiconductor industry for inspecting the raw material. To sum up the foregoing descriptions, if a process inspection method that can analyze suspended particles in the liquid and the base material immersed in a liquid environment and have a good resolution can be developed, the manufacturing efficiency can be improved.

### SUMMARY OF THE INVENTION

An electron microscope provided by the present invention comprises: a charged particle beam generator to generate a first charged particle beam to bomb an object; a detector to detect a second charged particle from the object to form an image; a film disposed downstream of the charged particle beam generator and having a first surface and a second surface, wherein a space between the charged particle beam generator and the first surface of the film is a vacuum environment; a bearing unit disposed at a side of the second surface of the film and having a bearing surface and a back surface, wherein the object is disposed on the bearing surface of the bearing unit, such that a distance between an analyzed surface of the object and the film is less than a predetermined spacing, and a liquid space exists between the analyzed surface and the film to be filled a liquid.

Preferably, the film and the bearing unit are connected detachably, and form an airtight container.

Preferably, the film and the bearing unit may be screwed into each other to form the airtight container.

Preferably, the bearing unit may be connected to a push rod, and the push rod pushes the bearing unit to be moved with respect to the film.

Preferably, the film and the bearing unit may be moved with respect to each other to adjust a distance between the film and the bearing unit.

Preferably, the film and the charged particle beam generator are connected to form the vacuum environment.

Preferably, the liquid space has a liquid inlet and a liquid outlet.

Preferably, a flow rate of the liquid flowing through the object is less than 500 mm/s.

Preferably, the electron microscope of the present invention further comprises a drive unit to drive at least one of the film and the bearing unit to be moved, so as to adjust a distance between the film and the bearing unit.

Preferably, the electron microscope of the present invention further comprises a drive unit to drive the film and the charged particle beam generator to be moved parallel to the bearing unit.

Preferably, the electron microscope of the present invention further comprises a temperature control unit disposed on the back surface of the bearing unit to adjust the object to a predetermined temperature.

Preferably, the temperature control unit comprises a flow channel passing through the back surface of the bearing unit to guide a heat transfer medium to flow through the back surface of the bearing unit.

Preferably, the predetermined spacing is less than a travelling distance of the first charged particle beam in the liquid.

Preferably, the predetermined spacing ranges from 1 nm to 5 mm.

Preferably, a material of the film comprises a semiconductor nitride, a semiconductor oxide, a metal nitride, a metal oxide, a polymer, a macromolecular material, graphite or graphene, graphite oxide or graphene oxide.

Preferably, a material of the bearing unit comprises at least one of a metal, a nitride, an oxide, a silicide, a polymer, a macromolecular material or a carbide.

The objective, technologies, features and advantages of the present invention will become apparent from the following description in conjunction with the accompanying drawings wherein certain embodiments of the present invention are set forth by way of illustration and example.

### BRIEF DESCRIPTION OF THE DRAWINGS

FIG. 1 is a schematic view of an electron microscope according to one embodiment of the present invention.

FIG. 2A and FIG. 2B are schematic views of the adjustment of the spacing between a film and a bearing unit according to one embodiment of the present invention.

FIG. 3A and FIG. 3B are schematic views of the adjustment of the spacing between the film and the bearing unit according to another embodiment of the present invention.

FIG. 4 is a schematic view of the adjustment of the spacing between the film and the bearing unit according to yet another embodiment of the present invention.

FIG. 5 is a schematic view of an electron microscope having a vacuum environment according to one embodiment of the present invention.

FIG. 6A is a schematic view of an electron microscope having a vacuum environment according to another embodiment of the present invention.

FIG. 6B is a schematic view of the electron microscope of FIG. 6A applied to a continuous process.

FIG. 7 is a schematic view of an electron microscope according to yet another embodiment of the present invention.

FIG. 8 is a schematic view of an electron microscope having a temperature control unit according to one embodiment of the present invention.

### DESCRIPTION OF THE PREFERRED EMBODIMENT

Various embodiments of the present invention will be described in detail below and illustrated in conjunction with the accompanying drawings. In addition to these detailed descriptions, the present invention can be widely implemented in other embodiments, and apparent alternations, modifications and equivalent changes of any mentioned embodiments are all included within the scope of the present invention and based on the scope of the Claims. In the descriptions of the specification, in order to make readers have a more complete understanding about the present invention, many specific details are provided; however, the present invention may be implemented without parts of or all the specific details. In addition, the well-known steps or elements are not described in detail, in order to avoid unnecessary limitations to the present invention. Same or similar elements in Figures will be indicated by same or similar reference numbers. It is noted that the Figures are schematic and may not represent the actual size or number of the elements. For clearness of the Figures, some details may not be fully depicted.

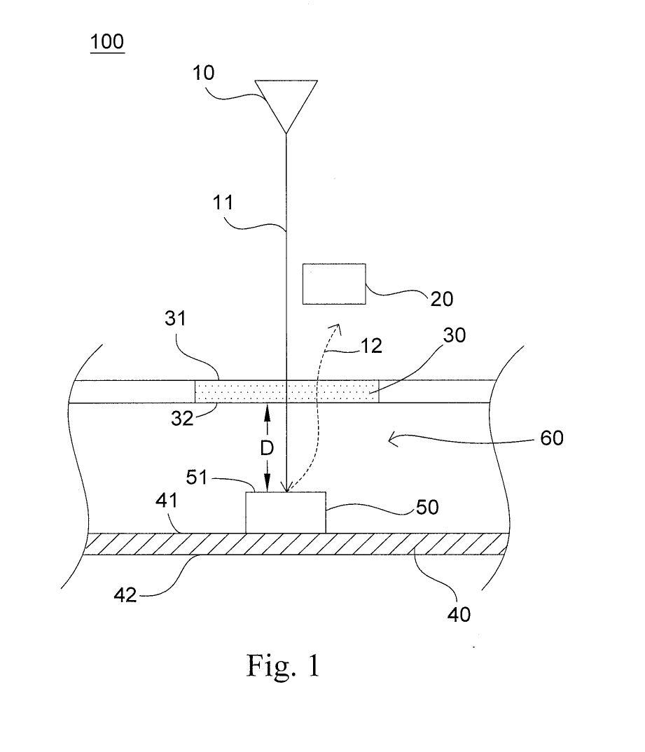

Referring to FIG. 1, an electron microscope 100 of the present invention comprises a charged particle beam generator 10 to generate a first charged particle beam 11 to bomb an object 50, and a detector 20 to detect a second charged particle 12 from the object 50 to form an image (not shown). For example, the second charged particle 12 may be a secondary electron or a back scattered electron and so on. A film 30 is disposed downstream of the charged particle beam generator 10 and has a first surface 31 and a second surface 32, wherein a space between the charged particle beam generator 10 and the first surface 31 of the film 30 is a vacuum environment. A bearing unit 40 is disposed at a side of the second surface 32 of the film 30 and has a bearing surface 41 and a back surface 42, wherein the object 50 is disposed on the bearing surface 41 of the bearing unit 40, such that a distance between an analyzed surface 51 of the object 50 and the film 30 is less than a predetermined spacing D, and a liquid space 60 exists between the analyzed surface 51 and the film 30 to be filled a liquid. Additionally, a material of the bearing unit comprises at least one of a metal, a nitride, an oxide, a high molecular material, a carbide, or a silicide.

It is noted that the liquid space is not limited to contain only a liquid, and it may contain only a gas or both a liquid and a gas or may be in a vacuum state. For example, before analyzing a process, the space may be filled with a gas or contain both a liquid and a gas during the course of liquid injection; during analyzing the process, the space may be filled with a liquid; during the reaction course of the process, a reaction gas may be generated, such that the space may contain both a liquid and a gas; after draining the liquid at the end of the process, the space may be pumped to be in vacuum before the beginning of the next process.

In addition, in the present invention, the predetermined spacing between the object on the bearing unit and the film is related to the energy of the first charged particle beam. With the Monte Carlo algorithm, the energy loss of the first charged particle beam into a liquid medium may be calculated, and a travelling distance (i.e., the total distance from incidence to stop) of the first charged particle beam in the liquid medium may be predicted. Based on the foregoing descriptions, it can be understood that when the predetermined spacing is too large, the first charged particle beam may be cancelled in the liquid and may not bomb the object. Thus, the predetermined spacing should be less than the travelling distance of the first charged particle beam in the liquid medium. Furthermore, the energy of the second charged particle generated after the first charged particle beam has bombed the object may be less than that of the first charged particle beam, and the travelling distance of the second charged particle in the liquid medium may be less as well. To facilitate the second charged particle to pass through the liquid medium and to be detected by the detector, the predetermined spacing preferably should be less than the travelling distance of the second charged particle in the liquid medium. It can be understood that the detector may be disposed in the liquid to detect the second charged particle. In one embodiment of the present invention, the predetermined spacing may range from 1 nm to 5 mm. In addition, the predetermined spacing may be adjusted by moving the film or the bearing unit according to the required focal length, which will be described in detail hereinafter.

It should be noted that the detector 20 in the present invention is illustratively depicted at the same side as the charged particle beam generator 10. However, the present invention is not limited to this, and the detector may be located at a different side from the charged particle beam generator, so as to detect the charged particle passing through the object to form an image.

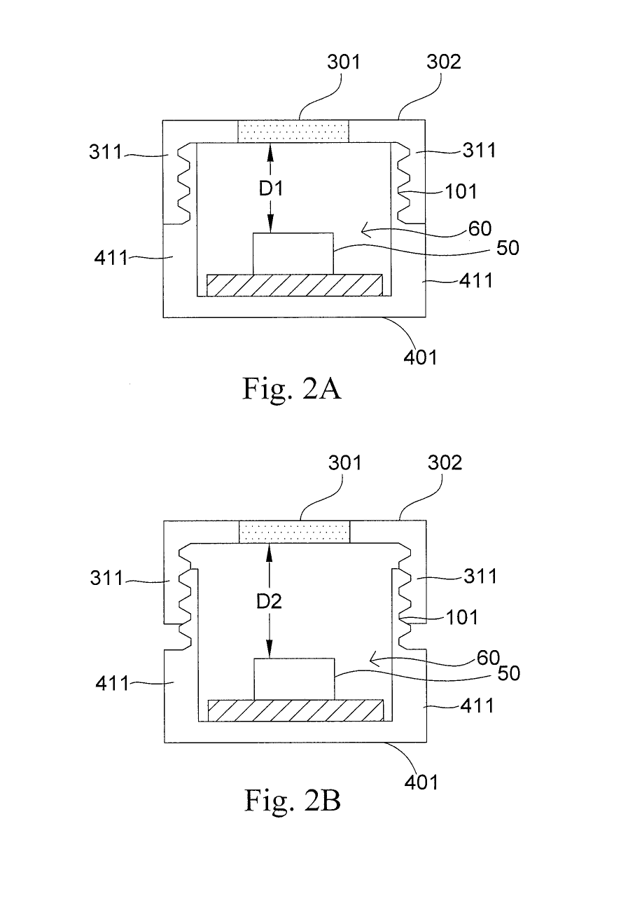

In one embodiment of the present invention, the film and the bearing unit are connected detachably, and form an airtight container. For example, referring to FIG. 2A and FIG. 2B, a film 301 may be disposed in a cover 302. Both sides of the cover 302 have one side wall 311 extending downwards, and both sides of a bearing unit 401 may have one side wall 411 extending upwards, such that the two side walls 311 of the cover 302 and the two side walls 411 of the bearing unit 401 may correspond to each other. For example, as shown in FIG. 2A and FIG. 2B, the side walls 311 and the side walls 411 may have corresponding thread structures 101, such that the film 301 and the bearing unit 401 may be screwed into each other to form an airtight space. As such, when the cover 302 is screwed in a direction away from the bearing unit 401 loaded with the object or in a direction toward the bearing unit 401, the predetermined spacing D1 and D2 between the film 301 and the object 50 may be adjusted, such that the first charged particle beam 11 may bomb the object 50, and the second charged particle 12 may pass through the film 301 and be detected by the detector 20. It is noted that, in the present invention, the side walls 311 of the film 301 and the side walls 411 of the bearing unit 401 are illustratively depicted as thread structures 101. However, the present invention is not limited to this, and the side walls 311 and 411 may be any corresponding configurations that may be locked to each other and separated from each other.

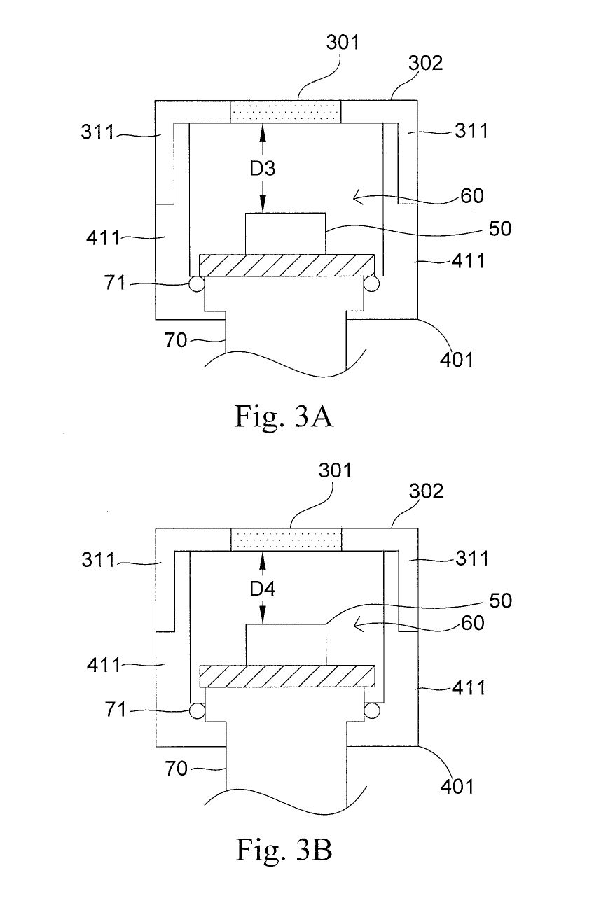

In another embodiment of the present invention, the bearing unit may be connected to a push rod to adjust the predetermined spacing. Referring to FIG. 3A and FIG. 3B, the bearing unit 401 and the push rod 70 may be connected to each other. When the push rod 70 moves the bearing unit 401 loaded with the object in a direction toward the film 301 or in a direction away from the film 301, the predetermined spacing D3 and D4 between the film 301 and the object 50 may be adjusted. Additionally, an 0 ring 71 may be disposed at the joint of the push rod 70 and the bearing unit 401 to achieve a tightly-joined effect. It is noted that, in the present invention, an O ring is used to join the push rod and the bearing unit tightly. However, the present invention is not limited to this, and the push rod and the bearing unit may have configurations that may be locked to each other and separated from each other, such as thread structures. The push rod may be screwed to move the bearing unit loaded with the object in a direction toward the film or in a direction away from the film.

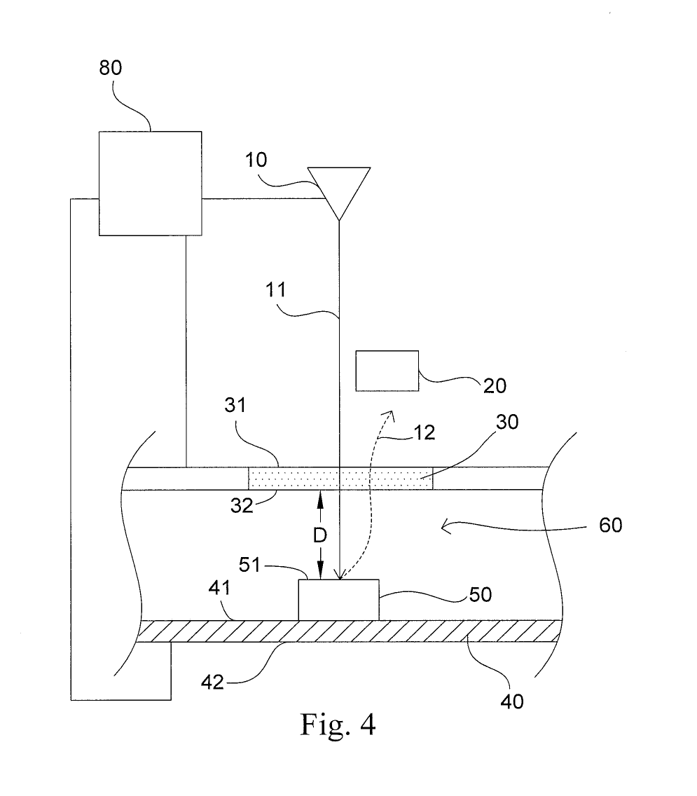

In yet another embodiment of the present invention, referring to FIG. 4, a drive unit 80 is further included to drive at least one of the film 30 and the bearing unit 40 to be moved, or drive the film 30 and the bearing unit 40 to be moved with respect to each other, thereby adjusting the predetermined spacing D5 between the film 30 and the bearing unit 40.

The drive unit 80 may also be used to drive the film 30 and the charged particle beam generator 10 to be moved in a direction parallel to the bearing unit 40, which may move the film together with the charged particle beam generator 10 transversely with respect to the bearing unit 40, so as to move the film together with the charged particle beam generator 10 to another inspection area of the object and achieve the effect of multi-point inspection.

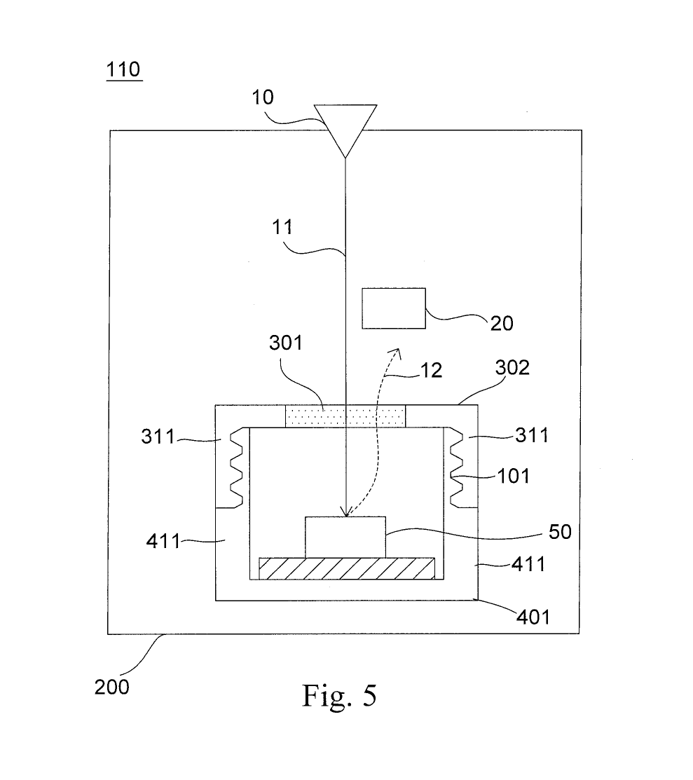

Referring to FIG. 5, in one embodiment of the present invention, an electron microscope 110 may further comprise a vacuum chamber 200.

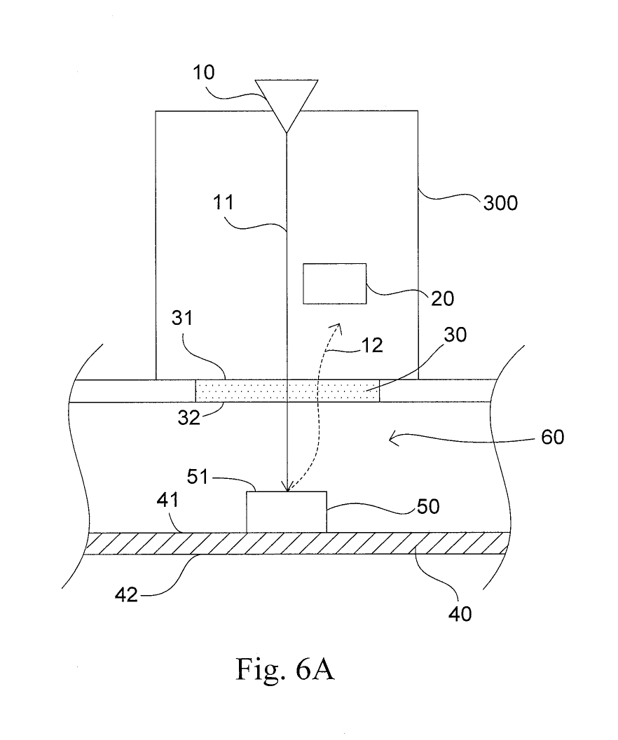

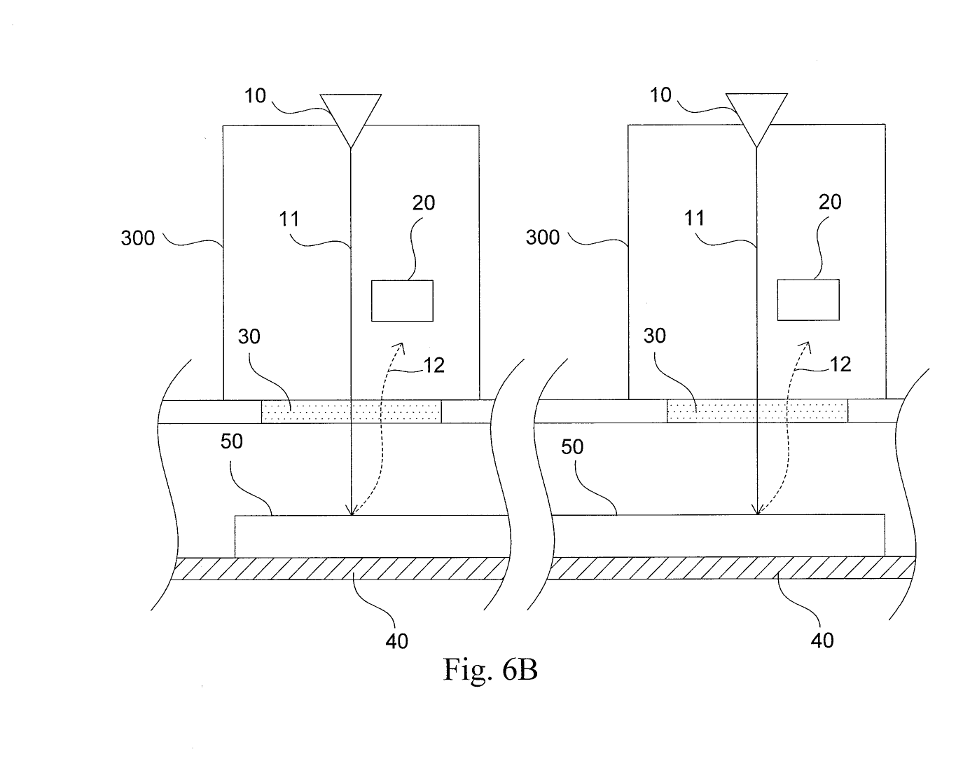

Moreover, the airtight container formed by the film 301 and the bearing unit 401 is disposed in the vacuum chamber 200, such that a space between the charged particle beam generator 10 and the film 301 is a vacuum environment. In yet another embodiment, referring to FIG. 6A, the film 30 and the charged particle beam generator 10 may be connected to each other with appropriate elements to form a vacuum chamber 300, thereby forming the vacuum environment between the charged particle beam generator 10 and the film 301. A sample for a general charged particle beam analyzing equipment needs to be in a vacuum environment, which puts certain limitation on the observation of a liquid or a water-contained sample.

However, with the above-mentioned configuration, the present invention has a vacuum environment between the charged particle beam generator and the film, and thus the present invention may be effectively applied in the inspection of a liquid or a water-contained sample. According to another embodiment, the electron microscope of the present invention may be applied to a continuous process. As shown in FIG. 6B, multiple electron microscopes may be arranged in a column to inspect a large object 50, such as a large wafer and so on.

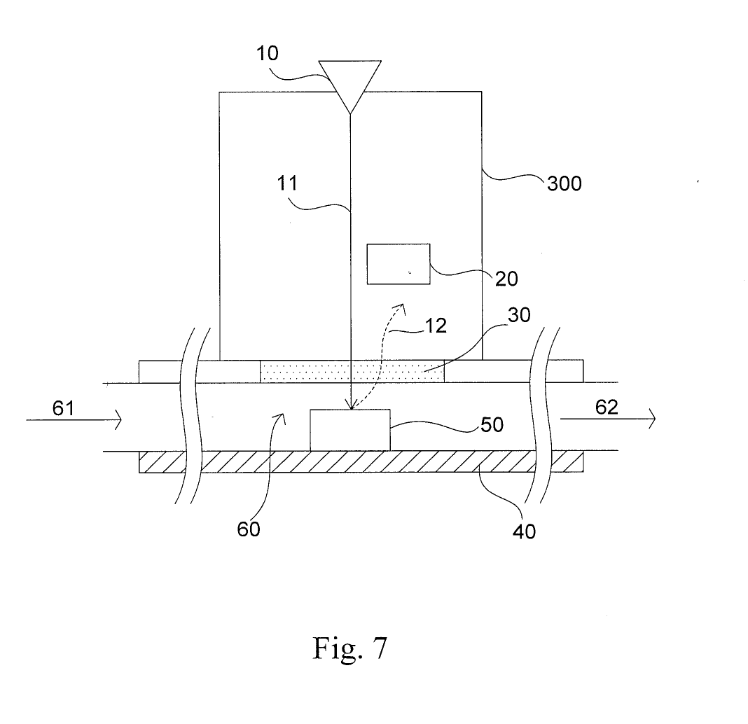

According to another embodiment of the present invention, referring to FIG. 7, the liquid space 60 between the object 50 and the film 30 may have a liquid inlet 61 and a liquid outlet 62 to provide a flow of the liquid in the liquid space 60. In other words, the present invention may inspect the object 50 in real-time during the process. Preferably, a flow rate of the liquid flowing through the object may be less than 500 mm/s in case the film should be damaged.

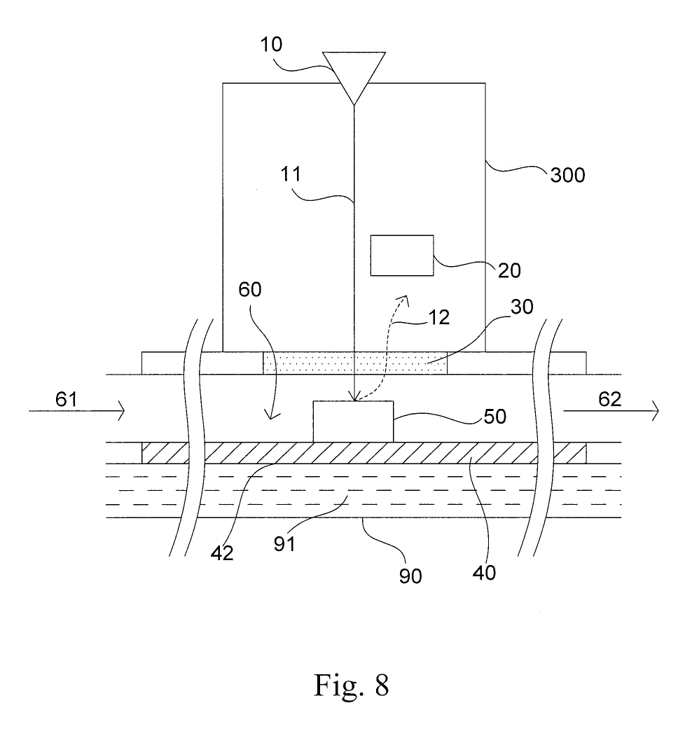

According to yet another embodiment of the present invention, referring to FIG. 8, an electron microscope may further comprise a temperature control unit 90 disposed on the back surface 42 of the bearing unit 40 to adjust the object 50 to a predetermined temperature. For example, the temperature control unit may comprise a flow channel passing through the back surface 42 of the bearing unit 40 to guide a heat transfer medium 91 to flow through the back surface 42 of the bearing unit 40, thereby adjusting the temperature of the object 50. However, the present invention is not limited to this, and disposing a temperature control element, such as a heating coil, on the back surface 42 of the bearing unit 40 may also achieve the purpose of temperature control.

The electron microscope of the present invention may detect the suspended particles in the liquid and the substrate material immersed in a liquid environment and may be applied to: a) the inspection of the liquid incoming material, e.g., the inspection of the impurity or the uniformity of dispersed phase of liquid raw materials such as photoresist/chemical/pure water, so as to avoid the losses caused by the material impurities or the gather of the dispersed phase; b) the inspection of the liquid material during a process, e.g., the dynamic record and inspection of the degradation state of the polishing slurry in use, so as to avoid a reduced yield due to a change of the polishing component and optimize the replacement time of the polishing liquid to reduce cost; c) the inspection of the substrate material immersed in a liquid, for example: during the developing, etching, plating, washing of the wafer, the change of the line width and patterns on the wafer may be inspected without making the wafer out of the liquid surface or a dry process; the effect of impurity removal on a surface during the washing process may be dynamically recorded; the generation and removal of the air bubbles during the etching process may be monitored; the growth or incorrect accumulation of metal during the plating process may be analyzed, etc.; thus, the yield of the process may be improved and the time for repeated drying inspection may be reduced.

In addition to the semiconductor process, the electron microscope of the present invention may be applied to the biomedical industry to observe the suspended particles and powder of medicines or additives dissolved in a liquid or the biological sample immersed in the nutrient solution (such as biological tissues, dressing or artificial medical materials, etc.). The electron microscope of the present invention may be applied to the manufacturing industry, such as the inspection of the change of the added granules of the lubrication oil after use, the detection of the size distribution and dispersion of the mixing powder and particles of the slurry material in the organic solution.

What is claimed is:

1. An electron microscope comprising:
a charged particle beam generator to generate a first charged particle beam to bomb an object;
a detector to detect a second charged particle from the object to form an image;
a film disposed downstream of the charged particle beam generator and having a first surface and a second surface, wherein a space between the charged particle beam generator and the first surface of the film is a vacuum environment; and
a bearing unit disposed at a side of the second surface of the film and having a bearing surface and a back surface, wherein the object is disposed on the bearing surface of the bearing unit, such that a distance between an analyzed surface of the object and the film is less than a predetermined spacing, and a liquid space exists between the analyzed surface and the film to be filled a liquid.

2. The electron microscope according to claim 1, wherein the film and the bearing unit are connected detachably, and form an airtight container.

3. The electron microscope according to claim 2, wherein the film and the bearing unit are screwed into each other to form the airtight container.

4. The electron microscope according to claim 2, wherein the bearing unit is connected to a push rod, and the push rod pushes the bearing unit to be moved with respect to the film.

5. The electron microscope according to claim 1, wherein the film and the bearing unit are moved with respect to each other to adjust a distance between the film and the bearing unit.

6. The electron microscope according to claim 1, wherein the film and the charged particle beam generator are connected to form the vacuum environment.

7. The electron microscope according to claim 1, wherein the liquid space has a liquid inlet and a liquid outlet.

8. The electron microscope according to claim 1, wherein a flow rate of the liquid flowing through the object is less than 500 mm/s.

9. The electron microscope according to claim 1, further comprising:
a drive unit to drive at least one of the film and the bearing unit to be moved, so as to adjust a distance between the film and the bearing unit.

10. The electron microscope according to claim 1, further comprising:
a drive unit to drive the film and the charged particle beam generator to be moved parallel to the bearing unit.

11. The electron microscope according to claim 1, further comprising:
a temperature control unit disposed on the back surface of the bearing unit to adjust the object to a predetermined temperature.

12. The electron microscope according to claim 11, wherein a temperature control unit comprises a flow channel passing through the back surface of the bearing unit to guide a heat transfer medium to flow through the back surface of the bearing unit.

13. The electron microscope according to claim 1, wherein the predetermined spacing is less than a travelling distance of the first charged particle beam in the liquid.

14. The electron microscope according to claim 1, wherein the predetermined spacing ranges from 1 nm to 5 mm.

15. The electron microscope according to claim 1, wherein a material of the film comprises a semiconductor nitride, a semiconductor oxide, a metal nitride, a metal oxide, a polymer, a macromolecular material, graphite or graphene, graphite oxide or graphene oxide.

16. The electron microscope according to claim 1, wherein a material of the bearing unit comprises at least one of a metal, a nitride, an oxide,or a silicide, a polymer, a macromolecular material or a carbide.
